(19) United States
(12) Patent Application Publication
(10) Pub. No.: US 2026/0140156 A1
(43) Pub. Date: May 21, 2026

(54) LOAD CONTROL PROBE DEVICE AND LOAD CONTROL METHOD

(71) Applicant: UNIMICRON TECHNOLOGY CORP., Taoyuan City (TW)

(72) Inventors: Chunhsien CHIEN, Taoyuan City (TW); ShihSian GUO, Taoyuan City (TW); Yu-Chung HSIEH, Taoyuan City (TW); Cheng-Hui WU, Taoyuan City (TW); Hsin-Hung LEE, Taoyuan City (TW)

(73) Assignee: UNIMICRON TECHNOLOGY CORP., Taoyuan City (TW)

(21) Appl. No.: 19/014,039

(22) Filed: Jan. 8, 2025

(30) Foreign Application Priority Data
Nov. 18, 2024 (TW) 113144299

(51) Int. Cl. G01R 29/08; G01B 11/06

(52) U.S. Cl. CPC G01R 29/0878; G01B 11/0608

(57) ABSTRACT

A load control probe device includes a probe module, a load sensor and a controller. The load sensor is connected to the probe module and used to measure the load data of the probe module, and the controller is connected to the probe module and the load sensor. A load control method, applicable for a probe module, includes: measuring, by a load sensor, load data of a probe module along a first direction, controlling the probe module to move along the first direction while simultaneously determining whether the load data meets a load setting value, and stopping the probe module from moving along the first direction and starting to control the probe module to perform signal detection when determining that the load data meets the load setting value.

### CROSS-REFERENCE TO RELATED APPLICATIONS

This non-provisional application claims priority under 35 U.S.C. § 119(a) on Patent Application No(s). 113144299 filed in Republic of China on Nov. 18, 2024, the entire contents of which are hereby incorporated by reference.

### BACKGROUND

### 1. Technical Field

This disclosure relates to a load control probe device and a load control method.

### 2. Related Art

Current automatic probe testing machines predominantly use a fixed-stroke probing measurement method. This involves using laser distance measurements prior to testing to record the surface height of the object under test. Each test point height is then sequentially compensated in the probe lifting system. Contact between the probe and the object under test is determined based on whether a signal is detected. The probe or the stage carrying the object under test is relatively moved for a fixed height to ensure contact between the probe and the object under test.

However, this method often leads to excessive probe wear and inconsistent load distribution among multiple probes or during repeated probing. This results in varying degrees of wear among probes, making it difficult to maintain consistent probe quality.

### SUMMARY

Accordingly, this disclosure provides a load control probe device and load control method.

According to an embodiment of this disclosure, a load control probe device comprises a probe module, a load sensor and a controller, wherein the load sensor is connected to the probe module, and configured to measure load data of the probe module along a first direction, wherein the controller is connected to the probe module and the load sensor, pre-storing a load setting value, and configured to control the probe module to move along the first direction while simultaneously determining whether the load data meets the load setting value, and to stop the probe module from moving along the first direction and to start to control the probe module to perform signal detection when determining that the load data meets the load setting value.

According to one or more embodiment of this disclosure, a load control method, applicable for a probe module, comprises measuring, by a load sensor, load data of a probe module along a first direction, controlling the probe module to move along the first direction while simultaneously determining whether the load data meets a load setting value, and stopping the probe module from moving along the first direction and starting to control the probe module to perform signal detection when determining that the load data meets the load setting value.

In view of the above description, the load control probe device and load control method of the present disclosure may regulate the load value when the probe contacts the object under test to meet a setting value. By controlling the force of the probe that contact with the object under test, the wear on the probe during each time of contact may be kept consistent. Therefore, the approach may prevent excessive probe wear while achieving stable measurements and improving the ability to manage probe quality.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram illustrating a load control probe device according to an embodiment of the present disclosure;

FIG. 2 is a schematic diagram illustrating the setup of a load control probe device according to an embodiment of the present disclosure;

FIG. 3 is a flowchart illustrating a load control method according to an embodiment of the present disclosure; and

FIG. 4 is a flowchart illustrating the signal detection method according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

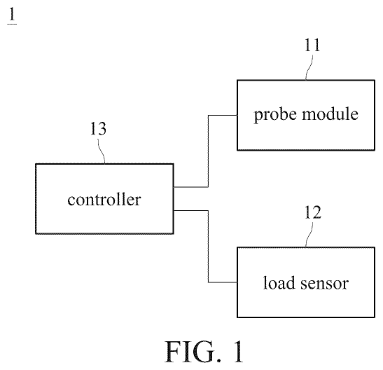

Please refer to FIG. 1, which is a block diagram illustrating a load control probe device according to an embodiment of the present disclosure. As shown in FIG. 1, the load control probe device 1 includes a probe module 11, a load sensor 12, and a controller 13. The controller 13 is connected to the probe module 11 and the load sensor 12 through wired or wireless connections. The load sensor 12 is structurally connected to the probe module 11 and is preferably positioned close to the probe module 11. For example, the load sensor 12 may be configured to have direct contact with the probe module 11.

The probe module 11 is connected to the controller 13, and is controlled by controller 13 to move along a first direction and controlled by controller 13 to perform signal detection. The first direction may be the direction of gravity or toward the object under test. The signal detection may involve testing an object under test placed on a stage. For instance, the probe module 11 may include a high-frequency probe head, and the object under test may be a product such as an antenna.

The load sensor 12 is configured to measure load data of the probe module 11 along the first direction. The load data may be expressed in grams (g) or newton (N). In one implementation, the load sensor 12 may be a strain sensor, piezoelectric material, or strain gauge. In another implementation, the load sensor 12 may include a base and a strain element. The base is pulled by the probe module 11, thereby causing the strain element to change the strain state. The strain elements may convert stress (e.g., pressure, torque, tension, or compression) into a readable electrical signal (as load data described in this disclosure). The strain element may be a conductor such as metal, ceramics, or composite material. For example, the base of the load sensor 12 is pulled by the downward movement of the probe module 11, and the strain element is pulled by the base so as to alter the strain state and generate a corresponding strain electrical signal which is then converted to load data and transmitted to the controller 13.

The controller 13 pre-stores a load setting value and is configured to control the probe module 11 to move along the first direction while simultaneously determining whether the load data meets the load setting value, and to stop the probe module from moving along the first direction and to start to control the probe module to perform signal detection when determining that the load data meets the load setting value. The controller 13 may include one or more processors, such as a central processing unit (CPU), graphics processing unit (GPU), microcontroller, programmable logic controller, or other processors with signal-processing function. The load setting value may range between 10 grams and 35 grams, preferably between 15 grams and 27 grams, and more preferably between 20 grams and 21 grams. For instance, the controller 13 may pre-store a load setting value of 20 grams. When receiving load data of 20 grams from the load sensor 12 that meets the pre-stored load setting value, the controller 13 may stop the probe module 11 from moving toward the object under test and start to control the probe module 11 to perform signal detection. The signal detection may involve the controller 13 using the probe module 11 to output a measurement signal to the object under test and receiving the corresponding signal, such as an electrical signal, to perform a functional test. In an embodiment, the controller 13 prevents the probe module 11 from performing signal detection until the load data meets the load setting value.

In an embodiment, the load control probe device 1 may further include a laser rangefinder connected to the controller 13 and configured to measure the surface height of the object under test. Before the controller 13 controls the probe module 11 to move along the first direction, the laser rangefinder may perform laser ranging on the object under test (e.g., an antenna substrate) to obtain and record the surface height of the object under test, and transmit the data to the controller 13. The controller 13 compensates the test point height of the object under test into the probe stroke and either raises the stage carrying the object under test or moves the probe module 11 toward the object under test, enabling the probe module 11 to contact the object under test.

In an embodiment, the probe module 11 may comprise a plurality of probes, and the load sensor 12 may measure a plurality of load values corresponding to the plurality of probes, as shown in Table 1 below.

TABLE 1
Load values measured by the load sensor
12 for multiple probes (unit: g)

| | | |
|---|---|---|
| 21.5190 | 21.5190 | 18.0000 |
| 21.7814 | 20.2532 | 19.5686 |
| 22.0000 | 20.2532 | 21.6667 |
| 21.0443 | 20.7278 | 21.6667 |
| 21.6667 | 21.6667 | 21.6667 |

In this embodiment, the load sensor 12 measures a plurality of load values generated by the plurality of probes and transmits the plurality of load values to the controller 13. The controller 13 stops the probe module 11 from moving toward the object under test and initiates detection when determining that the average of the plurality of load values reaches the load setting value pre-stored in the controller 13. For example, the pre-stored load setting value in the controller 13 is 21 grams, and when the load sensor 12 measures a plurality of probe load values as shown in Table 1 and transmits the plurality of probe load values to the controller 13, the controller 13 determines that the average of the plurality of probe load values is 21 grams which reaches the load setting value, and the controller 13 stops the movement of the probe module 11 toward the object under test and controls the probe module 11 to detect the object under test. Table 1 exemplifies the measurement data of fifteen probes; however, the number of probes in the probe module 11 is not limited to this.

In an embodiment, the controller 13, in addition to operations aforementioned, is further configured to display load data. For instance, the controller 13 may include a display screen. The controller 13 may receive load data from the load sensor 12, and present the load data to the user in a visual way. Furthermore, the controller 13 may directly control the load control probe device via Ethernet to take appropriate measures when detecting that the load data exceeds a preset safety range.

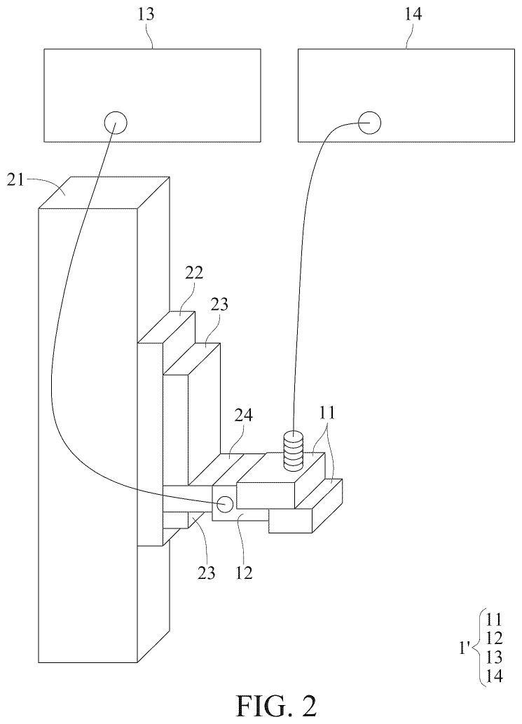

Please refer to FIG. 2, which is a schematic diagram illustrating the setup of a load control probe device according to an embodiment of the present disclosure. As shown in FIG. 2, the load control probe device 1′ includes a probe module 11, a load sensor 12, a controller 13, and an optional network analyzer 14, and may be disposed to a spindle 21 via a fixture 22, a clamping assembly 23, and a support element 24. The controller 13 is connected to the load sensor 12 and may be connected to the driving motor of the spindle 21. The controller 13 may be configured to move the spindle 21 along the first direction so as to bring the probe module 11 to move along the first direction through the fixture 22, clamping assembly 23, support element 24, and load sensor 12. The implements, functions, and operations of the probe module 11, load sensor 12, and controller 13 are consistent with those of the load control probe device 1 in FIG. 1 and would not be repeated here. The network analyzer 14 is an optional component.

The network analyzer 14 may be connected to the controller 13 through either a wired or wireless connection to receive and analyze signals. In an embodiment, the network analyzer 14 receives the corresponding signal generated during the signal detection performed by the probe module 11 for analysis.

The fixture 22 (e.g., a locking plate) is mounted on one side of the spindle 21 and is used to secure the clamping assembly 23. The clamping assembly 23 is disposed on one side of the fixture 22 and is used to clamp the support element 24. The support element 24 is disposed to connected with the fixture 22 and the load sensor 12 and is held in place by the clamping assembly 23. In an embodiment, the spindle 21, fixture 22, clamping assembly 23, and support element 24 may be implemented as part of a Z-axis lifting system. The controller 13 may be connected to the Z-axis lifting system through a wired or wireless connection to control the movement of the probe module 11. In an embodiment, a load control probe system may include the load control probe device 1′, spindle 21, fixture 22, clamping assembly 23, and support element 24. FIG. 2 provides an exemplary illustration of the relative positions of the components of the load control probe device F and other parts, but the present disclosure is not limited to this. The controller 13 may be mounted on the spindle 21 or other locations.

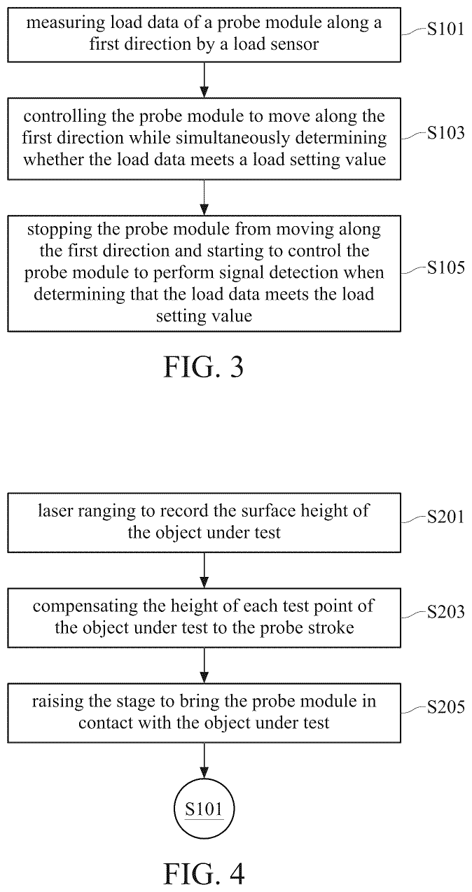

Please refer to FIG. 3, wherein FIG. 3 is a flowchart illustrating a load control method according to an embodiment of the present disclosure. As shown in FIG. 3, the load control method comprises step S101: measuring load data of a probe module along a first direction by a load sensor; step S103: controlling the probe module to move along the first direction while simultaneously determining whether the load data meets the load setting value; and step S105: stopping the probe module from moving along the first direction and starting to control the probe module to perform signal detection when determining that the load data meets the load setting value. The load control method is applicable for the load control probe device 1 shown in FIG. 1, and the following description describes the load control method with reference to the load control probe device 1 shown in FIG. 1.

In step S101, the load sensor 12 of the load control probe device 1 measures load data of the probe module 11 along the first direction. Specifically, the first direction may be the direction of gravity or toward the object under test, and the load data may be expressed in units of grams (g) or newton (N).

In step S103, the controller 13 of the load control probe device 1 controls the probe module 11 to move along the first direction while simultaneously determining whether the load data meets a load setting value. Specifically, the controller 13 may acquire the load data measured by the load sensor 12 while controlling the movement of the probe module 11, and determine whether the load data meets the load setting value. The load setting value may range between 10 grams and 35 grams, preferably between 15 grams and 27 grams, and more preferably between 20 grams and 21 grams.

In step S105, the controller 13 stops the probe module 11 from moving along the first direction and starts to control the probe module 11 to perform signal detection when determining that the load data meets the load setting value. Otherwise, the controller 13 continues to move the probe module 11 along the first direction and rechecks whether the load data meets the load setting value when the load data does not meet the load setting value.

In an embodiment where the probe module 11 includes a plurality of probes, the load data may include a plurality of load values corresponding to the plurality of probes, and step S103 in FIG. 3 may comprise: determining whether the average of the plurality of load values reaches the load setting value. Specifically, the load sensor 12 measures a plurality of load values for the plurality of probes and transmits the plurality of load values as load data to the controller 13. The controller 13 stops the probe module 11 from moving along the first direction and initiates signal detection when determining that the average of the plurality of load values reaches the pre-stored load setting value.

FIG. 4 is a flowchart illustrating the signal detection method according to an embodiment of the present disclosure. In this embodiment, the signal detection method as shown in FIG. 4 includes step S201: laser ranging to record the surface height of the object under test; step S203: compensating the height of each test point of the object under test to the probe stroke; step S205: raising the stage to bring the probe module in contact with the object under test; besides steps S201-S205, the method also includes steps S101-S105 as shown in FIG. 3. Specifically, step S101 in FIG. 3 may be executed after step S205 in FIG. 4. Specifically, before moving the probe module along the first direction, the controller may use the laser rangefinder to measure and record the surface height of the object under test, compensate for the test point height to the probe stroke, and either raise the stage carrying the object under test or move the probe module so that bringing the probe module in contact with the object under test. The controller stops the movement of the probe module and starts to control the probe module to perform signal detection when determining that the probe module has descended to the specified load value.

In view of the above description, the load control probe device and load control method of the present disclosure may regulate the load value when the probe contacts the object under test to meet a setting value. By controlling the force of the probe that contact with the object under test, the wear on the probe during each time of contact may be kept consistent. Therefore, the approach may prevent excessive probe wear while achieving stable measurements and improving the ability to manage probe quality. Moreover, with the display function of the controller and the adjustable load setting values, the load control probe device and load control method of the present disclosure may enable real-time monitoring of the load values of the probe device, allowing for corresponding adjustments during the measurement process.

What is claimed is:

1. A load control probe device, comprising:
a probe module;
a load sensor connected to the probe module, and configured to measure load data of the probe module along a first direction; and
a controller connected to the probe module and the load sensor, pre-storing a load setting value, and configured to control the probe module to move along the first direction while simultaneously determining whether the load data meets the load setting value, and to stop the probe module from moving along the first direction and to start to control the probe module to perform signal detection when determining that the load data meets the load setting value.

2. The load control probe device according to claim 1, wherein the load setting value is between 10 grams and 35 grams.

3. The load control probe device according to claim 2, wherein the load setting value is between 15 grams and 27 grams.

4. The load control probe device according to claim 1, wherein the probe module comprises a plurality of probes, the load data comprises a plurality of load values of the plurality of probes, and the controller is configured to stop the probe module from moving along the first direction and to start to control the probe module to perform signal detection when an average value of the plurality of load values reaches the load setting value.

5. The load control probe device according to claim 1, wherein the controller is further configured to display the load data.

6. The load control probe device according to claim 1, wherein the probe module comprises a high-frequency probe head.

7. A load control method, applicable for a probe module, comprising:
measuring, by a load sensor, load data of a probe module along a first direction;
controlling the probe module to move along the first direction while simultaneously determining whether the load data meets a load setting value; and
stopping the probe module from moving along the first direction and starting to control the probe module to perform signal detection when determining that the load data meets the load setting value.

8. The load control method according to claim 7, wherein the load setting value is between 10 grams and 35 grams.

9. The load control method according to claim 8, wherein the load setting value is between 15 grams and 27 grams.

10. The load control method according to claim 7, wherein the probe module comprises a plurality of probes, the load data comprises a plurality of load values of the plurality of probes, and determining whether the load data meets the load setting value comprises
determining whether an average value of the plurality of load values reaches the load setting value.
